(19) United States
(12) Patent Application Publication
(10) Pub. No.: US 2018/0016687 A1
(43) Pub. Date: Jan. 18, 2018

(54) METHOD FOR PRODUCING NANOIMPRINT TRANSFER BODY

(71) Applicant: KABUSHIKI KAISHA TOYOTA CHUO KENKYUSHO, Nagakute-shi (JP)

(72) Inventors: Atsushi MIURA, Nagakute-shi (JP); Yuri SASAKI, Nagakute-shi (JP); Hiroaki WAKAYAMA, Nagakute-shi (JP)

(73) Assignee: KABUSHIKI KAISHA TOYOTA CHUO KENKYUSHO, Nagakute-shi (JP)

(21) Appl. No.: 15/646,724

(22) Filed: Jul. 11, 2017

(30) Foreign Application Priority Data
Jul. 13, 2016 (JP) 2016-138926
Feb. 16, 2017 (JP) 2017-027133

(51) Int. Cl. C25D 1/00; C09D 183/10; C01B 33/12; G03F 7/00

(52) U.S. Cl. CPC C25D 1/006; G03F 7/0002; C09D 183/10; C01B 33/126; C01P 2002/30; C01P 2004/03

(57) ABSTRACT

A method for producing a nanoimprint transfer body includes the steps of: forming, on a substrate, a film including a block copolymer capable of microphase separation and an inorganic precursor incorporated in one polymer block component constituting the block copolymer or a polymer phase including the polymer block component; subjecting the block copolymer to microphase separation to form a microphase separated structure including the block copolymer and the inorganic precursor incorporated in the polymer block component or the polymer phase including the polymer block component; removing organic components from the microphase separated structure to form a nanostructure of an inorganic component; and forming a nanoimprint transfer body by using the nanostructure as a master mold.

### BACKGROUND OF THE INVENTION

### Field of the Invention

The present invention relates to a method producing a nanoimprint transfer body.

### Related Background Art

A nanoimprinting method is a technique for forming a pattern by sandwiching a resin layer between a base member and a master mold having a fine structure on the surface, and transferring the fine structure on the master mold surface to the resin layer. In conventional nanoimprinting methods, the master mold has been fabricated by subjecting a resist to treatments such as exposure, development, and etching. As a result, there have been problems, for example, that a large-scale system is required, and that it takes a long time to fabricate a master mold having a large-area and fine structure pattern.

Hence, as methods for fabricating a master mold having a large-area and fine structure pattern within a short time by a relatively simple process, there have been proposed methods which utilize a phase separation of a block copolymer. For example, International Publication No. WO2011/007878 (Patent Literature 1) states that a master block (master mold) having a fine structure on the surface is obtained by forming a microphase separated structure of a block copolymer. However, since this master mold is constituted of organic components (block copolymer), the solvent resistance and the strength are not sufficient. In addition, when a resin replica mold is fabricated from the master mold, the organic components are decomposed by heat or ultraviolet rays in some cases.

Moreover, International Publication No. WO2013/161454 (Patent Literature 2) states that a mold is obtained by: phase-separating a block copolymer to form a block copolymer film having a fine structure on a surface thereof and a horizontal cylinder structure in an interior thereof; forming a metal layer on the fine structure of the block copolymer film by electroforming; and releasing a base member having the fine structure from the metal layer. However, this method requires the step of forming a metal layer, in addition to the step of phase-separating a block copolymer. Further, since the materials forming the fine structure are organic components (block copolymer), the solvent resistance and the strength are not sufficient. Additionally, when the metal layer is formed, the organic components are decomposed by heat in some cases.

Meanwhile, Japanese Unexamined Patent Application Publication Nos. 2012-64878 (Patent Literature 3) and 2013-63576 (Patent Literature 4) and Y. Ootera et al., Jpn. J. Appl. Phys., 2013, vol. 52, pp. 105201-1 to 105201-5 (NPL 1) describe methods including: forming a self-assembly pattern on a substrate by utilizing self-assembly of a block copolymer; and forming a dot mold with a fine structure on the surface by using the self-assembly pattern. However, in the methods described in these literatures, polystyrene-b-polydimethylsiloxane is used as the block copolymer, and the self-assembly pattern made of the polydimethylsiloxane is formed. Nevertheless, this self-assembly pattern is merely utilized as a mask in the event of etching the substrate.

### SUMMARY OF THE INVENTION

The present invention has been made in view of the above-described problems of the conventional techniques. An object of the present invention is to provide a method for producing a nanoimprint transfer body, in which a nanostructure is fabricated by utilizing microphase separation attributable to self-assembly of a block copolymer, and the nanostructure is directly usable as a master mold.

The present inventors have earnestly studied in order to achieve the above object. As a result, the inventors have found out that: removing organic components from a microphase separated structure comprising a block copolymer capable of microphase separation and an inorganic precursor incorporated in one polymer block component constituting the block copolymer or a polymer phase comprising the polymer block component makes it possible to form a nanostructure of an inorganic component (inorganic nanostructure) excellent in solvent resistance and strength; further, the inorganic nanostructure is usable as a master mold as it is when a nanoimprint transfer body is produced. These findings have led to the completion of the present invention.

Specifically, a method for producing a nanoimprint transfer body of the present invention comprises the steps of:

forming, on a substrate, a film comprising a block copolymer capable of microphase separation and an inorganic precursor incorporated in one polymer block component constituting the block copolymer or a polymer phase comprising the polymer block component;

subjecting the block copolymer to microphase separation to form a microphase separated structure comprising the block copolymer and the inorganic precursor incorporated in the polymer block component or the polymer phase comprising the polymer block component;

removing organic components from the microphase separated structure to form a nanostructure of an inorganic component; and

forming a nanoimprint transfer body by using the nanostructure as a master mold.

In the method for producing a nanoimprint transfer body of the present invention,

the block copolymer (more preferably, a block copolymer of polystyrene and polydimethylsiloxane) preferably comprises the inorganic precursor (more preferably, Si) in the polymer block component (more preferably, polydimethylsiloxane), and

the inorganic precursor (more preferably, Si) is preferably converted to form the nanostructure of the inorganic component (more preferably, SiO₂).

Moreover, in the Method for producing a nanoimprint transfer body of the present invention,

a solvent vapor annealing process is preferably performed to subject the block copolymer to the microphase separation, and

the polymer phase containing the inorganic precursor in the microphase separated structure is preferably formed into a cylindrical shape.

Further, in the method for producing a nanoimprint transfer body of the present invention, at least an ultraviolet ozone treatment is preferably performed to remove the organic components from the microphase separated structure, forming the nanostructure of the inorganic component; more preferably, the ultraviolet ozone treatment is performed after the microphase separated structure is subjected to reactive ion etching; and particularly preferably, the ultraviolet ozone treatment is performed after the microphase separated structure is subjected to the reactive ion etching and then to an oxidation treatment.

Moreover, in the method for producing a nanoimprint transfer body of the present invention,

the nanostructure preferably consists of the inorganic component, and

the nanostructure preferably comprises the inorganic component having a cylindrical shape.

Furthermore, the method for producing a nanoimprint transfer body of the present invention makes it possible to:

form a resin mold whose surface has a surface structure transferred from the nanostructure by using the nanostructure as a master mold; and

then form a metal nano-arrangement (preferably, a Ni nano-arrangement) whose surface has a surface structure transferred from the resin mold by using the resin mold.

According to the present invention, the nanostructure fabricated by utilizing microphase separation of the block copolymer is directly usable as a master mold when a nanoimprint transfer body is produced.

### BRIEF DESCRIPTION OF THE DRAWINGS

FIG. 1 is a phase diagram of microphase separation conditions of a block copolymer.

FIG. 2A is a scanning electron micrograph showing a state of the surface of a microphase separated structure obtained in Example 1.

FIG. 2B is an enlarged photograph of the scanning electron micrograph shown in FIG. 2A.

FIG. 3 is a halftone image showing a two-dimensional Fourier-transformed (2D-FFT) image of the surface of the microphase separated structure obtained in Example 1.

FIG. 4 is a scanning electron micrograph showing a state of the surface of a SiO₂ obtained in Example 1.

FIG. 5 is an atomic force micrograph showing a state of the surface of a resin mold obtained in Example 1.

FIG. 6 is a scanning electron micrograph showing a state of the surface of a Ni nano-arrangement obtained in Example 1.

FIG. 7 is a scanning electron micrograph showing a state of the surface of a master mold after nanoimprinting was performed in Example 1.

FIG. 8 is a scanning electron micrograph showing a state of the surface of a master mold after nanoimprinting was performed in Comparative Example 1.

FIG. 9 is a scanning electron micrograph showing a state of the surface of a resin mold obtained in Comparative Example 1.

### DETAILED DESCRIPTION OF THE PREFERRED EMBODIMENTS

Hereinafter, the present invention will be described in detail based on preferred embodiments thereof.

A method for producing a nanoimprint transfer body the present invention comprises the steps of:

forming, on a substrate, a film comprising a block copolymer capable of microphase separation and an inorganic precursor incorporated in one polymer block component constituting the block copolymer or a polymer phase comprising the polymer block component;

subjecting the block copolymer to microphase separation to form a microphase separated structure comprising the block copolymer and the inorganic precursor incorporated in the polymer block component or the polymer phase comprising the polymer block component;

removing organic components from the microphase separated structure to form a nanostructure of an inorganic component; and

forming a nanoimprint transfer body by using the nanostructure as a master mold. Hereinafter, each of the steps will be described.

[Step of Forming Film]

The film formation step according to the present invention is a step of forming, on a substrate, a film comprising a block copolymer capable of microphase separation and an inorganic precursor. The state of the block copolymer and the inorganic precursor in the film formed by this step includes:

(i) a state in which the inorganic precursor is incorporated in a structure of one polymer block component constituting the block copolymer, and
(ii) a state in which the inorganic precursor is incorporated in a polymer phase comprising one polymer block component constituting the block copolymer.

The block copolymer used in the present invention is not particularly limited, as long as it is capable of microphase separation through the self-assembly; in other words, polymer block components are immiscible with each other and satisfy predetermined microphase separation conditions. The block copolymer has a structure in which two or more types of polymer chains (polymer block components) are covalently bonded to each other. The polymer phases comprising the respective polymer block components do not separate from each other in a macroscopic scale, but undergo phase separation in a microscopic scale as small as the chain length. The polymer phases which are phase-separated in such a microscopic scale can form various ordered structures such as lamellar, spherical, and cylindrical structures, depending on the size and the composition of the block copolymer, the interaction of the polymer block components, orientation control, and so forth.

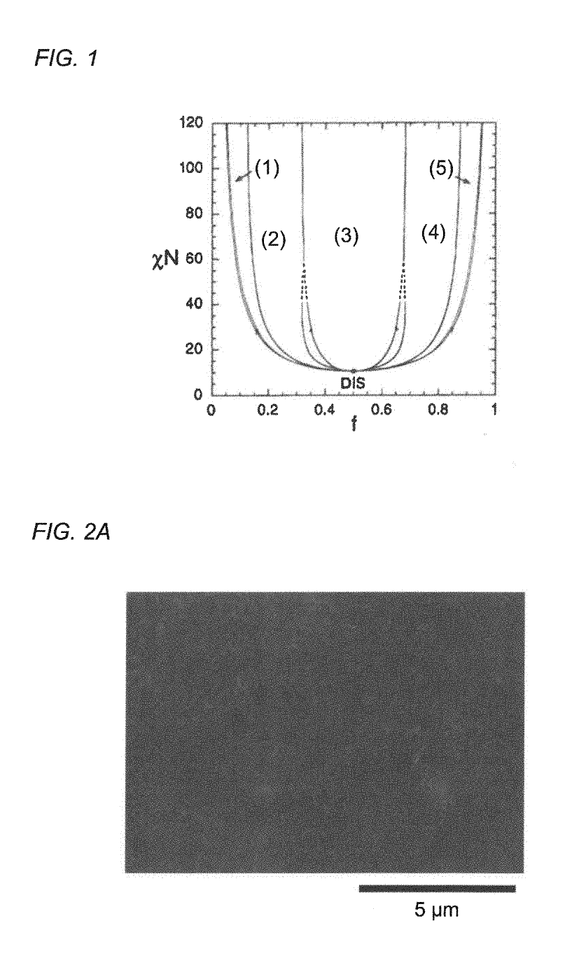

Hence, hereinbelow, a microphase separated structure of the block copolymer will be described using a phase diagram (Macromolecules, 1996, vol. 29, pp. 1092 to 1098) of microphase separation conditions of a block copolymer shown in FIG. 1. The microphase separated structure of the block copolymer depends on the degree of polymerization N of the block copolymer and the Flory-Huggins interaction parameter χ between the polymer block components. There is a tendency that the larger the values of the degree of polymerization N and the interaction parameter χ, the more likely the microphase separation is to occur. The formed microphase separated structure varies depending on volume fractions f of the polymer block components. For example, in a block copolymer constituted of a polymer block component A and a polymer block component B which are immiscible but linked to each other, the following structural changes occur in a region where a product χN of the degree of polymerization N and the interaction parameter χ is large as shown in FIG. 1, depending on χN and the volume fraction f of the polymer block component B.

(1) The polymer block component A in a spherical shape is present in a matrix made from the polymer block component B.
(2) The polymer block component A in a cylindrical shape is present in a matrix made from the polymer block component B.
(3) The polymer block component A and the polymer block component B form lamellar structures.
(4) The polymer block component B in a spherical shape is present in a matrix made from the polymer block component A.
(5) The polymer block component B in a cylindrical shape is present in a matrix made from the polymer block component A.

On the other hand, in a region where χN is small (a region (6) in FIG. 1), no phase separation, occur, resulting in a disordered state. For example, in a case where the volume fraction f of the polymer block component B is 0.5, if χN is less than 10.5, no phase separation occurs, and a lamellar structure as formed in the region (3) in FIG. 1 is not formed.

In the present invention, it is necessary to subject the block copolymer to microphase separation. Hence, the volume fraction f of the polymer block component, and the degree of polymerization N and the interaction parameter χ of the block copolymer are set as appropriate based on the phase diagram of microphase separation conditions shown in FIG. 1, and a desired block copolymer is selected. Note that the phase diagram of microphase separation conditions shown in FIG. 1 (i.e., the shapes of the curves) varies depending on the type of the block copolymer.

Examples of such a block copolymer capable of microphase separation include block copolymers each containing an inorganic precursor in the structure of one polymer block component (block copolymers capable of forming the state (i)) such as polystyrene-polydimethylsiloxane (PS-b-PDMS), polyvinylidene difluoride-poly(t-butyl acrylate) (PVDF-b-P(t-BuA)), polyvinylidene difluoride-polystyrene (PVDF-b-PS), polystyrene-polysilsesquioxane (PS-b-PSSQ), poly(methyl methacrylate)-polysilsesquioxane (PMMA-b-PSSQ), polylactic acid-polydimethylsiloxane-polylactic acid (PLA-b-PDMS-b-PLA), polystyrene-poly(ferrocenyldimethylsilane) (PS-b-PFS), and poly(ferrocenyldimethylsilane)-poly(methyl methacrylate) (PFS-b-PMMA); and block copolymers containing no inorganic precursor in the structures (block copolymers capable of forming the state (ii)) such as polystyrene-poly(methyl methacrylate) (PS-b-PMMA), polystyrene-poly(ethylene oxide) (PS-b-PEO), polystyrene-polyvinylpyridine (PS-b-PVP), polystyrene-polyisoprene (PS-b-PI), polystyrene-polybutadiene (PS-b-PB), poly(ethylene oxide)-polyisoprene (PEO-b-PI), poly(ethylene oxide) polybutadiene (PEO-b-PB), poly(ethylene oxide)-poly(methyl methacrylate) (PEO-b-PMMA), poly(ethylene oxide)-poly(ethyl ethylene) (PEO-b-PEE), polybutadiene-polyvinylpyridine b-PVP), polyisoprene-poly(methyl methacrylate) (PI-b-PMMA), polystyrene-poly (acrylic acid) (PS-b-PAA), and polybutadiene-poly(methyl methacrylate) (PB-b-PMMA). Among such block copolymers, from the viewpoint of easily obtaining a microphase separated structure comprising an inorganic precursor in one polymer phase, preferable are block copolymers each containing an inorganic precursor (preferably Si) in the structure of one polymer block component, more preferable are block copolymers containing polydimethylsiloxane as one polymer block component, and particularly preferable is PS-b-PDMS. Moreover, from the viewpoint that an inorganic precursor is easily introduced into one polymer phase, preferable are block copolymers containing polymer block components which greatly differ from each other in polarity, and particularly preferable are PS-b-PVP, PS-b-PFO, and PS-b-PAA.

In the present invention, the molecular weights of the block copolymer and the polymer block components constituting the block copolymer should be selected as appropriate in accordance with the structure scale and the arrangement. For example, the number average molecular weight of the block copolymer is preferably 100 to 10,000,000, and more preferably 1000 to 1,000,000. Note that there is a tendency that the lower the number average molecular weight of the block copolymer, the smaller the structure scale. Moreover, with regards to the number average molecular weight of the polymer block components, adjusting the molecular weight ratio of the polymer block components, and so forth, makes it possible to obtain a microphase separated structure having a desired structure attributable to the self-assembly in the step of forming a microphase separated structure to be described later. Consequently, the inorganic component can be arranged in a desired form. Further, in the present invention, in the step of forming a nanostructure to be described later, the organic components need to be removed, thereby leaving only the inorganic component. Accordingly, it is preferable to use: a block copolymer which can be easily decomposed by heat treatment (calcination), ultraviolet irradiation, reactive ion etching, oxygen plasma, or the like; or a block copolymer which can be easily removed with a solvent.

Meanwhile, the inorganic precursor which can be incorporated in the polymer phase comprising one polymer block component constituting the block copolymer (inorganic precursor capable of forming the state (ii)) is preferably at least one selected from the group consisting of various salts (for example, carbonates, nitrates, phosphates, sulfates, chlorides, and the like of metals or metalloids), various alkoxides (for example, methoxides, ethoxides, propoxides, butoxides, and the like containing metals or metalloids), various complexes (for example, acetylacetonate complexes and the like of metals or metalloids), and various organometallic compounds (for example, phenyltrimethoxysilane, cobaltocene, and the like). After such an inorganic precursor is converted, the resulting inorganic component is preferably at least one selected from the group consisting of oxides, metals, carbides, nitrides, borides, and salts to be described later. From the viewpoint that it is possible to expect that various functions are demonstrated, the inorganic component preferably contains at least one element selected from the group consisting of iron (Fe), aluminum (Al), niobium (Nb), cobalt (Co), nickel (Ni), platinum (Pt), tellurium (Te), titanium (Ti), and silicon (Si). Accordingly, examples of the inorganic precursors suitably used in the present invention include: salts such as carbonates, nitrates, phosphates, sulfates, and chlorides containing the above element; alkoxides such as methoxides, ethoxides, propoxides, and butoxides containing the above element; complexes such as acetylacetonates including Fe(acac)₃, Co(acac)₃, Pt(acac)₂, and Ni(acac)₂; and organometallic compounds such as phenyltrimethoxysilane and cobaltocene.

In the film formation step according to the present invention, the block copolymer, and the inorganic precursor if the inorganic precursor is not incorporated in the structure of the block copolymer, are preferably dissolved in a solvent to form the film by using an obtained raw material solution. The solvent used here is not particularly limited, as long as it is capable of dissolving the block copolymer to be used and the inorganic precursor added as necessary. Examples thereof include acetone, tetrahydrofuran (THF), cyclohexane, toluene, propylene glycol monomethyl ether acetate (PGMEA), propylene glycol monomethyl ether (PGME), chloroform, benzene, and the like. One of these solvents may be used alone, or two or more thereof may be used in combination.

Note that, in the present specification, the term “dissolve” means such a phenomenon that a substance (solute) is dissolved in a solvent to form a homogeneous mixture (solution), and includes cases where after dissolved, at least part of the solute becomes ions, where the solute is not dissociated into ions but exists in the form of molecules, where the solute exists as associating molecules and ions, and other similar cases.

The ratios of the solutes (the block copolymer, the inorganic precursor) in the raw material solution are not particularly limited. Given that all the amount of the raw material solution is 100% by mass, a total amount of the solutes is preferably approximately 0.1 to 30% by mass, and more preferably 0.5 to 10% by mass. Moreover, in the case where the inorganic precursor is added, adjusting the amount of the inorganic precursor added to the block copolymer makes it possible to adjust the amount of the inorganic component finally introduced, and the inorganic component in the obtained nanostructure may have a desired size.

The method for forming the film is not particularly limited. For example, spin coating, dip coating, inkjet printing, a doctor blade method, a vapor deposition method, or the like can be employed as appropriate. From the viewpoint of obtaining a highly uniform film thickness in a simple manner, spin coating is particularly preferable. Moreover, the substrate is not particularly limited. It is possible to use, for example, a quartz substrate, a glass substrate, a silicon substrate, a substrate on which a film of a transparent conductive material such as fluorine-doped tin oxide (PTO) or tin-doped indium oxide (ITO) is formed, or other similar substrates.

[Step of Forming Microphase Separated Structure]

The step of forming a microphase separated structure according to the present invention is a step of subjecting the block copolymer to microphase separation to form a microphase separated structure comprising the block copolymer and the inorganic precursor. The state of the block copolymer and the inorganic precursor in the microphase separated structure formed by this step includes:

(i) a state in which the inorganic precursor is incorporated in a structure of one polymer block component constituting the block copolymer, and
(ii) a state in which the inorganic precursor is incorporated in a polymer phase comprising one polymer block component constituting the block copolymer.

The method for subjecting the block copolymer to microphase separation includes methods of applying an external field, such as electric field or magnetic field, to the film obtained in the film formation step, and methods of stretching the film obtained in the film formation step by shear flow. These promote the microphase separation of the block copolymer, and can make the internal structure of the microphase separated structure in an equilibrium state. Moreover, in the present invention, the microphase separation is preferably promoted by performing a thermal annealing process, a thermal gradient process, a solvent vapor annealing process, or the like. In the thermal annealing process, the temperature is kept within the glass transition temperature of the block copolymer or more and the order-disorder phase transition temperature or less. Meanwhile, in the solvent vapor annealing process, the film is kept in a solvent atmosphere for a predetermined time. These impart a high mobility to each polymer block component, making it possible to promote the orientation and the phase separation. Among these promotion processes, the solvent vapor annealing process is preferable (more preferably, a vapor annealing process using an organic solvent) from the viewpoint of enabling the arrangement within a shorter time than the thermal annealing.

Further, in the solvent vapor annealing, the same solvent as that used for dissolving the block copolymer can be used. Nevertheless, the solvent is preferably selected as appropriate in accordance with the solubility parameter of the block copolymer. Here, the “solubility parameter” is what is called “SP value” defined by the regular solution theory introduced by Hildebrand, and is a value obtained based on the following equation Solubility parameter δ [(cal/cm³)^{1/2}]=(ΔE/V)^{1/2} (where ΔE represents a molar energy of vaporization [cal], and V represents a molar volume [cm³]).

In a case of using a solvent having a solubility parameter close to that of the polymer block component A of the polymer block components A and B constituting the block copolymer, the solvent acts only on the polymer block component A, and increases the apparent volume fraction of the polymer block component A, so that the structure changes. Thus, it is preferable to select an organic solvent as appropriate in accordance with a desired microphase separated structure to use the vapor of the organic solvent to perform the vapor annealing process. Moreover, the vapor annealing process time can be set as appropriate in accordance with the molecular weight of the block copolymer and a desired microphase separated structure. Normally, the vapor annealing process is performed at normal temperature for 5 minutes to 48 hours (preferably within a range of 15 minutes to 4 hours). If the vapor annealing process time is less than the lower limit, the solvent does not sufficiently permeate into the block copolymer in some cases. On the other hand, if the vapor annealing process time exceeds the upper limit, a further structural change tends not to occur, so that the operation time is consumed in vain in some cases.

In the microphase separated structure formed as described above, the polymer phase containing the inorganic precursor has such a shape as columnar, spherical, lamellar, or cylindrical shape, and is arranged in the other polymer phase.

[Step of Forming Nanostructure]

The step of forming a nanostructure according to the present invention is a step of removing organic components from the microphase separated structure to form a nanostructure of an inorganic component (inorganic nanostructure). Specifically, in this step, the inorganic precursor is converted to an inorganic component. The inorganic component thus formed has a shape corresponding to the shape (such as columnar, spherical, lamellar, or cylindrical shape) of the polymer block component or the polymer phase containing the inorganic precursor. The obtained nanostructure has, on the surface, a fine structure (fine uneven structure) corresponding to the shape of the inorganic component.

The method for removing the organic components from the microphase separated structure and converting the inorganic precursor to the inorganic component includes heat treatment (calcination), ultraviolet irradiation, reactive ion etching, oxygen plasma, electron beam irradiation, wet etching with a solvent, and the like. The processing conditions in these methods are set as appropriate in accordance with the types and amounts of the organic components to be removed and the inorganic precursor to be converted, and so forth.

It is necessary that the nanostructure obtained as described above should comprise no organic component, in other words, the nanostructure should consist of the inorganic component. Thus, the nanostructure is obtained which firmly binds to the substrate surface, and the nanostructure can be used as a master mold repeatedly in the step of forming a nanoimprint transfer body to be described later. On the other hand, if an organic component remains in the nanostructure, sufficient solvent resistance and strength (particularly, the binding strength between the nanostructure and the substrate) are not obtained, and the nanostructure collapses or is released from the substrate in the step of forming a nanoimprint transfer body to be described later. Hence, the nanostructure cannot be used as a master mold, and it is difficult to form a desired fine structure on the surface of a resin mold and the like.

In the present invention, any analysis method may be adopted, as long as it is possible to confirm that the obtained nanostructure comprises no organic component. For example, infrared spectroscopy is conducted on the nanostructure obtained by performing the above-described process on the microphase separated structure. When it is found that only a peak derived from the inorganic component is detected and no peak derived from organic components is detected in the obtained infrared absorption spectrum, it can be confirmed that all the organic components are removed from the microphase separated structure, and that the nanostructure consists of the inorganic component and comprises no organic component. More specifically, in the case where polystyrene-b-polydimethylsiloxane (PS-b-PDMS) is used as the block copolymer, since the peaks of SiO₂, PDMS, and PS are detected at 1100 cm⁻¹, 1260 cm⁻¹, and 699 cm⁻¹, respectively, it should be confirmed that only the peak at 1100 cm⁻¹ is detected and the peaks of PDMS and PS are not detected in the obtained infrared absorption spectrum of the nanostructure. Further, as the method for confirming that the organic components are removed as described above, X-ray photoelectron spectroscopy (XPS), time-of-flight secondary ion mass spectrometry (TOF-SIMS), or the like can also be adopted besides the infrared spectroscopy.

[Step of Forming Nanoimprint Transfer Body]

The step of forming a nanoimprint transfer body according to the present invention is a step of forming a nanoimprint transfer body by using the nanostructure as a master mold.

In the present invention, the method for forming a nanoimprint transfer body (nanoimprinting method) is not particularly limited, as long as the nanostructure is used as a master mold. The method includes a thermal nanoimprinting method, a photo nanoimprinting method, an inking nanoimprinting method, and the like.

For example, in the thermal nanoimprinting method, a thermoplastic resin layer is formed on a substrate, and the nanostructure as a master mold is stacked on the thermoplastic resin layer such that the fine structure (fine uneven structure) on the nanostructure surface is transferred thereto. The resultant was pressurized while heated to the glass transition temperature or more. Next, the thermoplastic resin layer is cured by cooling and then released from the nanostructure (master mold). Thus, a resin mold is obtained in which the fine structure (fine uneven structure) is transferred to the surface of the thermoplastic resin layer. The heating-pressurizing conditions, cooling condition, and so forth in the thermal nanoimprinting method are not particularly limited, and are set as appropriate depending on the type of the thermoplastic resin to be used, and so forth. In such a thermal nanoimprinting method, although it is necessary to consider problems such as a decrease in imprinting precision and the damage to the master mold due to the high thermal history and pressurization, there are advantages that: many types of thermoplastic resins are applicable, and it is possible to form molds from a wide range of resin materials.

Moreover, in the photo nanoimprinting method, an energy-ray curable resin layer is formed on a substrate, and the nanostructure as a master mold is stacked on the energy-ray curable resin layer such that the fine structure (fine uneven structure) on the nanostructure surface is transferred thereto. Next, the energy ray curable resin layer is cured by irradiation with an energy ray (such as ultraviolet ray, visible light, electromagnetic wave), while pressurized as necessary. The resulting cured resin layer is released from the nanostructure (master mold). Thus, a resin mold is obtained in which the fine structure (fine uneven structure) is transferred to the surface of the cured resin layer. The energy-ray irradiation condition and so forth in the photo nanoimprinting method are not particularly limited, and are set as appropriate depending on the type of the energy-ray curable resin to be used, and so forth. In such a photo nanoimprinting method, a liquid resin having a low viscosity at normal temperature can be applied onto the substrate, and the resin layer can be cured by irradiation with an energy ray. Hence, there is an advantage that a finer surface structure can be transferred.

Moreover, by using the resin mold thus formed, the present invention makes it possible to form a metal nano-arrangement whose surface has a surface structure transferred from the resin mold. For example, a metal seed layer is formed on the surface of the resin mold which has the fine structure (fine uneven structure). Further, metal layer is stacked on the metal seed layer to thus obtain a metal nano-arrangement whose surface has the fine structure (fine uneven structure) transferred from the resin mold. The metal constituting such a metal nano-arrangement (comprising the metal seed layer and the metal layer) is not particularly limited. Examples thereof include nickel, copper, gold, silver, tin, alloys thereof, and the like. In addition, the method for forming the metal seed layer includes vapor deposition, adsorption, sputtering, electron beam epitaxy, and the like. The method for forming the metal layer includes electroforming, electroplating, electroless plating, and the like.

### EXAMPLES

Hereinafter, the present invention will be described more specifically based on Examples and Comparative Examples. However, the present invention is not limited to the following Examples.

### Example 1

<Step of Forming Film>

First, polystyrene-b-polydimethylsiloxane (PS-b-PDMS) as a block copolymer comprising an inorganic precursor Si in the structure was dissolved in 5 ml of tetrahydrofuran (THF) such that the concentration was 3% by mass. The obtained raw material solution was applied onto a silicon substrate. Thus, a thin film was formed. Note that, in the PS-b-PDMS, PS had a molecular weight of 31×10³, and PDMS had a molecular weight of 14.5×10³.

<Step of Forming Microphase Separated Structure>

Next, the obtained thin film was kept in a saturated chloroform vapor for 1.5 hours to promote the microphase separation of PS-b-PDMS. Thus, a microphase separated structure in which PDMS was arranged in the PS matrix was formed on the entire surface of the silicon substrate.

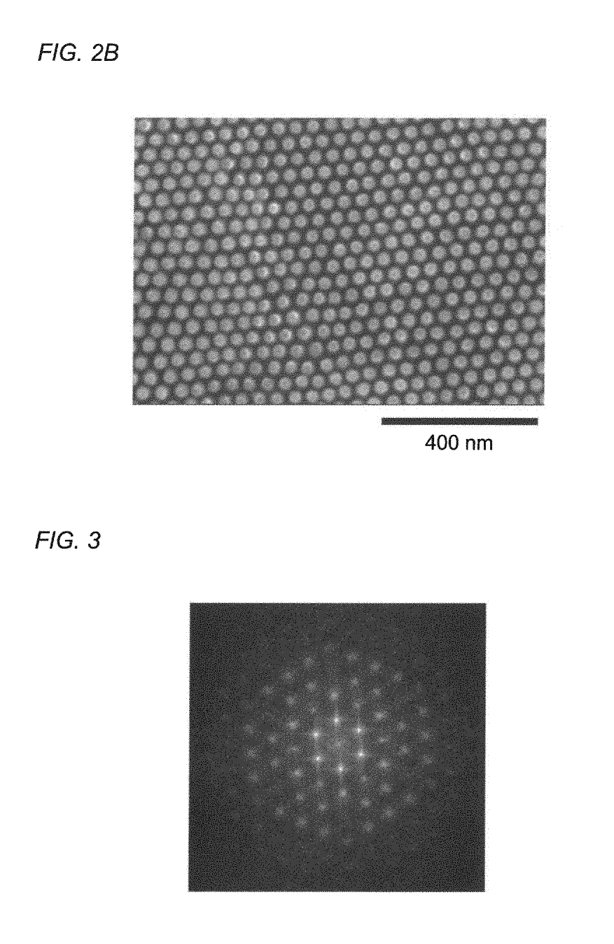

The surface of the obtained microphase separated structure was observed using a scanning electron microscope (SEM). FIG. 2A shows a SEM image of the surface of the microphase separated structure, and FIG. 2B shows an enlarged image thereof. As shown in FIGS. 2A and 2B, it was found that a cylindrical pattern was formed on the entire surface of the microphase separated structure. The cylinders had diameters of approximately 30 nm, and the distances thereamong were 44 nm. Moreover, FIG. 3 shows a two-dimensional Fourier-transformed (2D-FFT) image of the surface of the microphase separated structure. As shown in FIG. 3, since a hexagonal spot was clearly observed even at the degree of 5 in the 2D-FFT image, it was found that vertical cylinders of PDMS were formed in the obtained microphase separated structure and were orderly oriented in the form of hexagonal lattice.

<Step of Forming Nanostructure>

Next, the obtained microphase separated structure was subjected to a reactive ion etching (RIE) process using a gas mixture of CF₄ and O₂ to remove PS and to oxidize PDMS. Thus, a SiO₂ nanostructure was formed. Specifically, the gas mixture of CF₄ and O₂ was introduced into the chamber at a flow rate of CF₄/O₂ 59/10 sccm under conditions of the power: 100 W and the pressure in the chamber: 16 Pa. The microphase separated structure was subjected to the RIE process for 40 seconds. Next, 02 was introduced into the chamber at a flow rate of 10 cm³/minute under conditions of the power: 100 W and the pressure in the chamber: 10 Pa, and the structure after the RIE process was oxidized for 20 seconds. Then, O₂ was introduced into an ultraviolet ozone generator at a flow rate of 7 cm³/minute to subject the structure after the oxidation to an ultraviolet ozone treatment at 70° C. for 90 minutes. Thus, a SiO₂ nanostructure was formed on the silicon substrate.

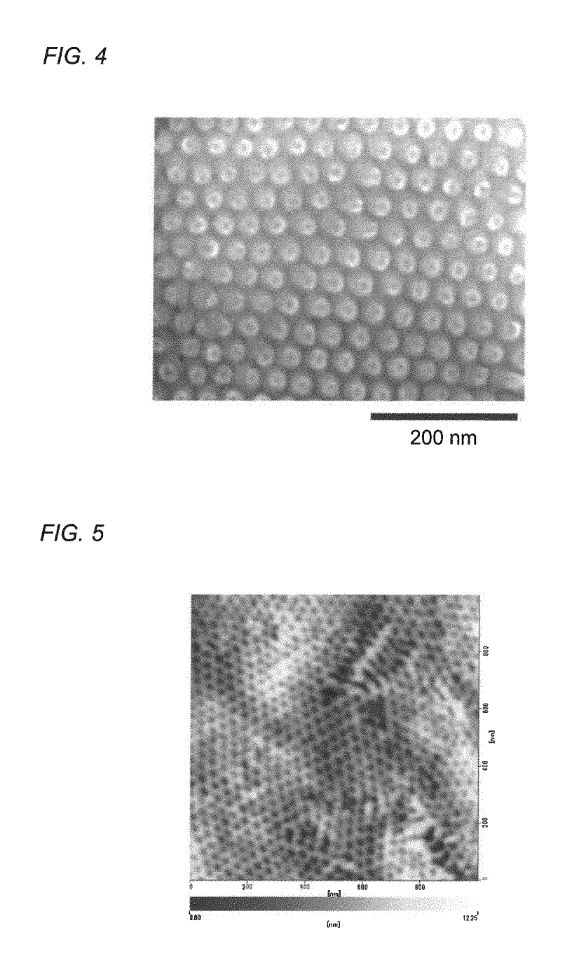

The surface of the obtained SiO₂ nanostructure was observed using a SEM. FIG. 4 shows a SEM image of the surface of the SiO₂ nanostructure. As shown in FIG. 4, the Pattern on the surface of the microphase separated structure was maintained on the surface of the SiO₂ nanostructure, too. It was found that an orderly hexagonal nano-dot structure was formed thereon.

In addition, infrared spectroscopy was conducted on the obtained SiO₂ nanostructure. The SiO₂ nanostructure was analyzed as it is by a macro transmission method. The obtained infrared absorption spectrum was subjected to a spectral subtraction process to remove the peak of the substrate, and peak intensities of SiO₂ (peak position: 1100 cm⁻¹), PDMS (peak position: 1260 cm⁻¹), and PS (peak position: 699 cm⁻¹) were determined. In the obtained SiO₂ nanostructure, the peak derived from SiO₂ was detected, but the peaks derived from PS and PDMS were not detected. It was found that the microphase separated structure was converted to the SiO₂ nanostructure entirely made of the inorganic component.

<Nanoimprinting Step>

Next, on the SiO₂ nanostructure as a master mold, a UV curable resin was added dropwise, and an acrylic resin was tightly bonded thereon to allow the UV curable resin to sufficiently infiltrate into the fine structure (hexagonal nano-dot structure) on the surface of the SiO₂ nanostructure. Then, the acrylic resin side was irradiated with ultraviolet rays to cure the UV curable resin. Thus, a resin mold was obtained. The resin mold was released from the master mold (the SiO₂ nanostructure). A Ni seed layer was formed by sputtering on the surface of the resin mold having a hole structure. After a Ni layer was further stacked on the Ni seed layer by electroforming (electroplating), the Ni layer was released from the resin mold. Thus, a Ni nano-arrangement was obtained.

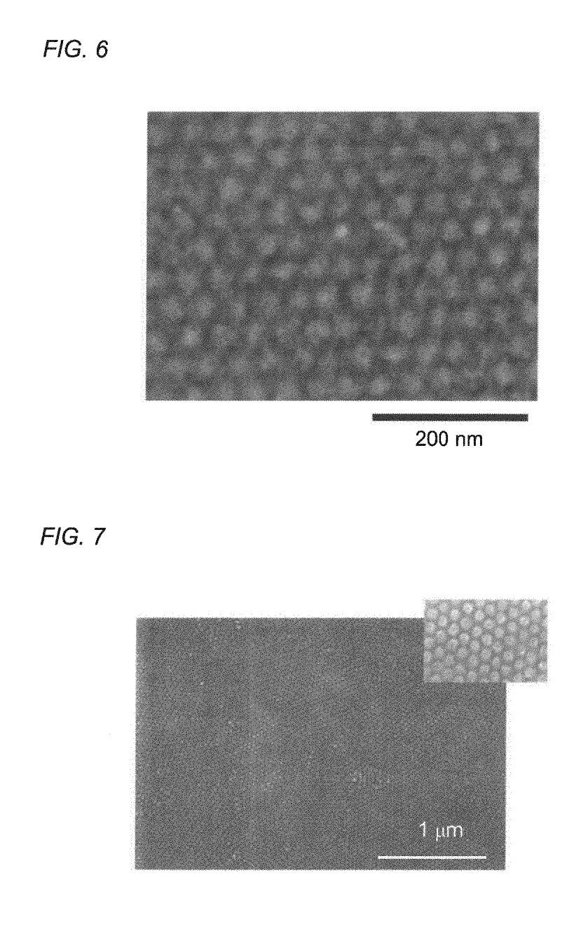

The surface of the obtained resin mold was observed using an atomic force microscope (AFM). Moreover, the surface of the obtained Ni nano-arrangement was also observed using a SEM. FIG. 5 shows an AFM image of the surface of the resin mold, and FIG. 6 shows a SEM image of the surface of the Ni nano-arrangement. As shown in FIG. 5, the hole structure corresponding to the fine structure on the surface of the SiO₂ nanostructure was formed on the surface of the resin mold. This confirmed that the nano-dot structure on the surface of the SiO₂ nanostructure was transferred to the surface of the resin mold. Further, as shown in FIG. 6, it was confirmed that the same nano-dot structure as that of the SiO₂ nanostructure (FIG. 4) was formed on the surface of the Ni nano-arrangement. These verified that a nanoimprint transfer body was obtained from an inorganic master mold by the present invention.

Furthermore, after the resin mold was released (after the nanoimprinting), the surface of the master mold (the SiO₂ nanostructure) was observed using a SEM. FIG. 7 shows a SEM image of the surface of the master mold after the nanoimprinting (an enlarged SEM image is shown in the upper right). As shown in FIG. 7, the fine structure (hexagonal nano-dot structure) on the surface of the master mold (the SiO₂ nanostructure) before the nanoimprinting was also observed clearly on the surface of the master mold after the nanoimprinting. No defect such as cracks and collapse of the nano-dot structure was observed before and after the nano imprinting.

### Comparative Example 1

In the same manner as in Example 1, a microphase separated structure in which PDMS was arranged in the PS matrix was formed on the entire surface of a silicon substrate. Next, a gas mixture of CF₄ and O₂ was introduced into the chamber at a flow rate of CF₄/O₂=59/10 sccm under conditions of the power: 100 W and the pressure in the chamber: 16 Pa. The microphase separated structure was subjected to the RIE process for 40 seconds. Then, O₂ was introduced into the chamber at a flow rate of 10 cm³/minute under conditions of the power: 50 W and the pressure in the chamber: 10 Pa, and the structure after the RIE process was oxidized for 10 seconds.

The infrared spectroscopy was conducted on the obtained structure in the same manner as in Example 1. Not only the peak derived from SiO₂ (peak position: 1100 cm⁻¹) but also the peaks derived from PDMS (peak position: 1260 cm⁻¹) and PS (peak position: 599 cm⁻¹) were detected. These revealed that the organic components remained in the obtained structure. It was tried to fabricate a resin mold using such a structure as a master mold in the same manner as in Example 1. However, it was impossible to transfer the long periodic pattern to the surface of the resin mold.

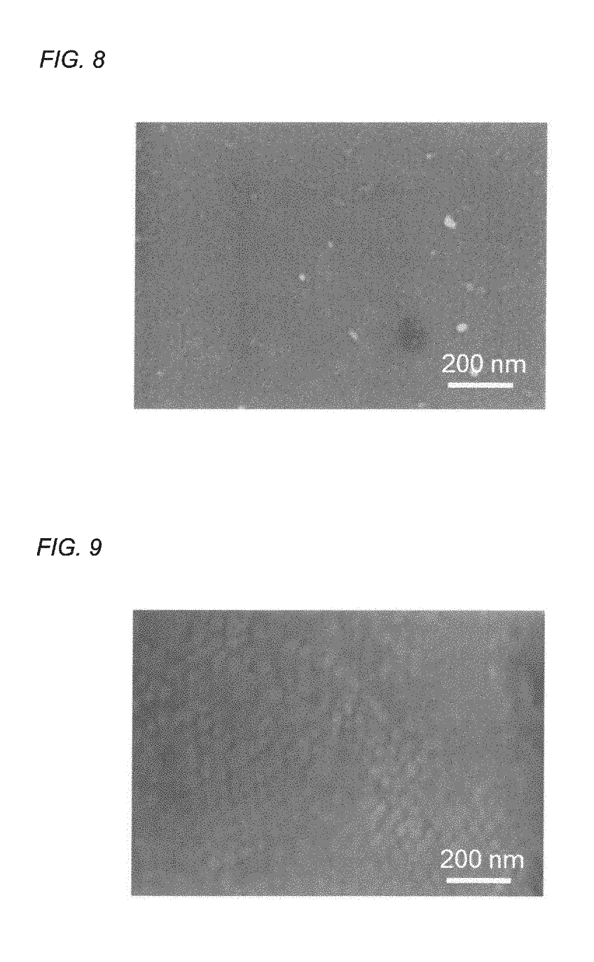

Then, after the resin mold was released (after the nanoimprinting), the surfaces of the master mold (the SiO₂ nanostructure) and the resin mold were observed using a SEM. FIG. 8 shows a SEM image of the surface of the master mold after the nanoimprinting, and FIG. 9 shows a SEM image of the surface of the resin mold. As shown in FIG. 8, no nano-dot structure was observed on the surface of the master mold after the nanoimprinting. On the other hand, as shown in FIG. 9, a nano-dot structure was observed on the surface of the resin mold. These results revealed that when the nanoimprinting was performed using the structure with the organic components remaining, the nano-dot structure on the surface of the structure was released from the silicon substrate and attached to the resin mold. The reason is speculated that, in the structure with the organic components remaining, the nano-dot structure is not firmly binding to the silicon substrate. Thus, it was found out that the structure with the organic components remaining did not function as a master mold for nanoimprinting.

The above results confirmed that when a nanostructure was used as a master mold to form a nanoimprint transfer body, it was necessary to sufficiently remove organic components from a microphase separated structure comprising a block copolymer and an inorganic precursor incorporated in one polymer block component constituting the block copolymer, thus forming an inorganic nanostructure.

Moreover, it was verified that it was possible to repeatedly use the inorganic nanostructure as a master mold, the inorganic nanostructure being formed by sufficiently removing organic components from the microphase separated structure.

As has been described above, according to the present invention, the nanostructure fabricated by utilizing microphase separation of the block copolymer is directly usable as a master mold repeatedly when a nanoimprint transfer body is produced.

Therefore, the method for producing a nanoimprint transfer body of the present invention makes it possible to produce a nanoimprint transfer body having a large-area and fine structure pattern at a low cost within a short time, and is useful in producing next-generation nanoimprint transfer bodies. Particularly, the method is useful in producing metal nano-arrangements having fine structure patterns whose applications are expected in the fields of biotechnology (biochips, high-sensitive sensors, bio-batteries), optics, and magnetism, and other fields.

What is claimed is:

1. A method for producing a nanoimprint transfer body, comprising the steps of:
forming, on a substrate, a film comprising a block copolymer capable of microphase separation and an inorganic precursor incorporated in one polymer block component constituting the block copolymer or a polymer phase comprising the polymer block component;
subjecting the block copolymer to microphase separation to form a microphase separated structure comprising the block copolymer and the inorganic precursor incorporated in the polymer block component or the polymer phase comprising the polymer block component;
removing organic components from the microphase separated structure to form a nanostructure of an inorganic component; and
forming a nanoimprint transfer body by using the nanostructure as a master mold.

2. The method for producing a nanoimprint transfer body according to claim 1, wherein
the block copolymer comprises the inorganic precursor in the polymer block component, and
the inorganic precursor is converted to form the nanostructure of the inorganic component.

3. The method for producing a nanoimprint transfer body according to claim 2, wherein
the inorganic precursor is Si, and
the inorganic component constituting the nanostructure is SiO₂.

4. The method for producing a nanoimprint transfer body according to claim 3, wherein the polymer block component comprising the inorganic precursor is polydimethylsiloxane.

5. The method for producing a nanoimprint transfer body according to claim 4, wherein the block copolymer is a block copolymer of polystyrene and polydimethylsiloxane.

6. The method for producing a nanoimprint transfer body according to claim 1, wherein a solvent vapor annealing process is performed to subject the block copolymer to the microphase separation.

7. The method for producing a nanoimprint transfer body according to claim 1, wherein the polymer phase containing the inorganic precursor in the microphase separated structure is formed into a cylindrical shape.

8. The method for producing a nanoimprint transfer body according to claim 1, wherein at least an ultraviolet ozone treatment is performed to remove the organic components from the microphase separated structure, forming the nanostructure of the inorganic component.

9. The method for producing a nanoimprint transfer body according to claim 8, wherein the ultraviolet ozone treatment is performed after the microphase separated structure is subjected to reactive ion etching.

10. The method for producing a nanoimprint transfer body according to claim 9, wherein the ultraviolet ozone treatment is performed after the microphase separated structure is subjected to the reactive ion etching and then to an oxidation treatment.

11. The method for producing a nanoimprint transfer body according to claim 1, wherein the nanostructure consists of the inorganic component.

12. The method for producing a nanoimprint transfer body according to claim 1, wherein the nanostructure comprises the inorganic component having a cylindrical shape.

13. The method for producing a nanoimprint transfer body according to claim 1, comprising:
forming a resin mold whose surface has a surface structure transferred from the nanostructure by using the nanostructure as a master mold; and
then forming a metal nano-arrangement whose surface has a surface structure transferred from the resin mold by using the resin mold.

14. The method for producing a nanoimprint transfer body according to claim 13, wherein the metal nano-arrangement is a Ni nano-arrangement.
